(19) United States
(12) Patent Application Publication
(10) Pub. No.: US 2025/0063655 A1
(43) Pub. Date: Feb. 20, 2025

(54) MEMBRANE CIRCUIT BOARD

(71) Applicant: Primax Electronics Ltd., Taipei (TW)

(72) Inventors: Lei-Lung Tsai, Taipei (TW); Che-An Li, Taipei (TW)

(21) Appl. No.: 18/368,471

(22) Filed: Sep. 14, 2023

(30) Foreign Application Priority Data
Aug. 16, 2023 (CN) 202311032621.3

(51) Int. Cl. H05K 1/09; H05K 1/02

(52) U.S. Cl. CPC H05K 1/092; H05K 1/0296; H05K 2201/0323

(57) ABSTRACT

A membrane circuit board is provided, which has at least one switch region. The membrane circuit board includes first and second membranes, a spacer layer, a first carbon ink contact, and a corresponding contact. The second membrane is located over the first membrane. The spacer layer is located between the first and second membranes, and has an opening in the switch region. The first carbon ink contact is disposed on one of a portion of an upper surface of the first membrane corresponding to the opening and a portion of a lower surface of the second membrane corresponding thereto. The corresponding contact corresponds to the first carbon ink contact, and is disposed on the other thereof. The corresponding contact is a second carbon ink contact or a conductive contact, and resistance of the conductive contact is less than resistance of the first carbon ink contact.

### FIELD OF THE INVENTION

The present disclosure relates to a membrane circuit board, in particular to a membrane circuit board for preventing ghost key phenomenon from occurring.

### BACKGROUND OF THE INVENTION

With the rapid development of science and technology, the vigorous development of electronic equipment has brought many conveniences to human life, so how to make the operation of the electronic equipment more humanized is an important issue. Common input devices of the electronic equipment include a mouse, a keyboard device, and a trackball device, among which the keyboard device can allow the user to directly input characters and symbols into the computer, so it is highly valued.

Generally, the main design of the keyboard is to arrange a plurality of key structures into a matrix form, which can also be called a keyboard matrix. When the user presses one of the keys, the keyboard controller scans columns and rows, and receives corresponding signals from the rows and columns to identify which key is pressed.

However, the key states of the keyboard matrix are mutually influenced. If the user presses multiple keys at the same time, the keyboard controller may misjudge. For example, when the user presses several nearby keys at the same time, another nearby key that is not pressed may be conducted successfully and thus misjudged as being pressed. This misjudged key can be called a ghost key. In order to prevent ghost key phenomenon, a diode can be arranged near each key contact, and the diode can make the current in the membrane switch circuit flow in a single direction. However, disadvantages of arranging the diode near each key contact is that the cost is too high and the manufacturing process is too complicated.

### SUMMARY OF THE INVENTION

The present disclosure provides a membrane circuit board, which includes has at least one switch region. The membrane circuit board includes a first membrane, a second membrane, a spacer layer, a first carbon ink contact and a corresponding contact. The second membrane is located over the first membrane. The spacer layer is located between the first membrane and the second membrane, and has an opening in the at least one switch region. The first carbon ink contact is disposed on one of a portion of an upper surface of the first membrane corresponding to the opening and a portion of a lower surface of the second membrane corresponding to the opening. The corresponding contact corresponds to the first carbon ink contact, and is disposed on the other of the portion of the upper surface of the first membrane corresponding to the opening and the portion of the lower surface of the second membrane corresponding to the opening. The corresponding contact is a second carbon ink contact or a conductive contact, and resistance of the conductive contact is less than resistance of the first carbon ink contact.

In some embodiments of the present disclosure, the membrane circuit board has a plurality of switch regions and a peripheral region surrounding the switch regions, and there is no carbon ink material disposed on another portion of the upper surface of the first membrane in the peripheral region and another portion of the lower surface of the second membrane in the peripheral region.

In some embodiments of the present disclosure, the membrane circuit board further includes a first conductive wire connected to the first carbon ink contact.

In some embodiments of the present disclosure, the first carbon ink contact includes a main pattern and a connection pattern connected to the main pattern, and the connection pattern is also connected to the first conductive wire.

In some embodiments of the present disclosure, one end of the first conductive wire overlaps with the first carbon ink contact.

In some embodiments of the present disclosure, the first conductive wire does not surround the first carbon ink contact.

In some embodiments of the present disclosure, the first conductive wire surrounds at least a portion of the first carbon ink contact.

In some embodiments of the present disclosure, the corresponding contact is the second carbon ink contact, and the membrane circuit board further includes a second conductive wire connected to the second carbon ink contact.

In some embodiments of the present disclosure, the corresponding contact is the conductive contact, which includes a first portion and a second portion, and the first portion and the second portion are separated by a gap.

In some embodiments of the present disclosure, the corresponding contact is the conductive contact, and two ends of the conductive contact are separated by a gap.

### BRIEF DESCRIPTION OF THE DRAWINGS

Aspects of the present disclosure are best understood from the following embodiments, read in conjunction with accompanying drawings. However, it should be understood that in accordance with common practice in the industry, various features have not necessarily been drawn to scale. Indeed, shapes of the various features may be suitably adjusted for clarity, and dimensions of the various features may be arbitrarily increased or decreased.

FIG. 1 is an exploded perspective view of a membrane circuit board according to an embodiment of the present invention.

FIG. 2 is a top view of a first membrane, a first carbon ink contact and a first conductive wire according to an embodiment of the present invention.

FIG. 3 is an exploded perspective view of a membrane circuit board according to an embodiment of the present invention.

FIG. 4 is an exploded perspective view of a membrane circuit board according to an embodiment of the present invention.

FIG. 5 is an exploded perspective view of a membrane circuit board according to an embodiment of the present invention.

FIG. 6 is an exploded perspective view of a membrane circuit board according to an embodiment of the present invention.

### DETAIL DESCRIPTION OF THE PREFERRED EMBODIMENT

The advantages and features of the present disclosure and the method for achieving the same will be described in more detail with reference to exemplary embodiments and accompanying drawings to make it easier to understand. However, the present disclosure can be implemented in different forms and should not be construed as being limited to the embodiments set forth herein. On the contrary, for those skilled in the art, the provided embodiments will make this disclosure more thorough, comprehensive and complete to convey the scope of the present disclosure.

The spatially relative terms in the text, such as “beneath” and “over”, are used to facilitate the description of the relative relationship between one element or feature and another element or feature in the drawings. The true meaning of the spatially relative terms includes other orientations. For example, when the drawing is flipped up and down by 180°, the relationship between the one element and the other element may change from “beneath” to “over.” The spatially relative descriptions used herein should be interpreted the same.

As mentioned in background of the invention, there may be ghost key phenomenon that occurs on the existing keyboard. Although the diode may be arranged near each key contact to prevent the ghost key phenomenon from occurring, the cost of this method is too high and the manufacturing process is too complicated. Accordingly, the present invention provides a membrane circuit board for preventing the ghost key phenomenon from occurring by disposing a high-resistance first carbon ink contact as a contact in a specific switch region. When the high-resistance contact is in contact with another contact, a matrix signal with a specific high impedance value is generated for a processor to identify, which can effectively prevent the ghost key phenomenon from occurring. Various embodiments of the membrane circuit board of the present invention will be described in detail below.

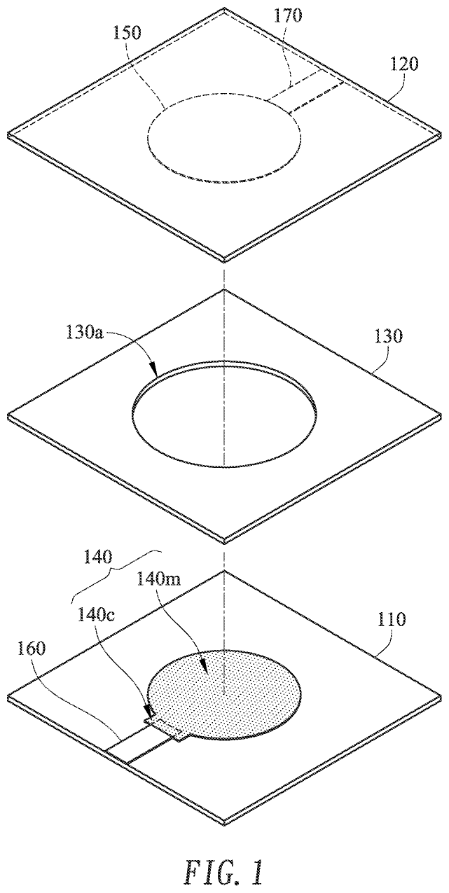

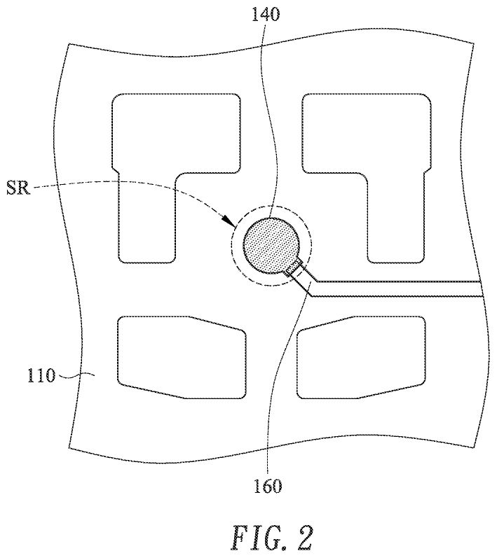

FIG. 1 is an exploded perspective view of a membrane circuit board according to an embodiment of the present invention. As shown in FIG. 1, the membrane circuit board includes a first membrane 110, a second membrane 120, a spacer layer 130, a first carbon ink contact 140 and a corresponding contact 150. FIG. 2 is a top view of a first membrane, a first carbon ink contact and a first conductive wire according to an embodiment of the present invention. As shown in FIG. 2, the membrane circuit board has at least one switch region SR.

As shown in FIG. 1, the second membrane 120 is located over the first membrane 110. The spacer layer 130 is located between the first membrane 110 and the second membrane 120. The spacer layer 130 has an opening 130a in a switch region (refer to the switch region SR of FIG. 2). The location of the opening 130a in FIG. 1 corresponds to the switch region SR in FIG. 2. In other words, the opening 130a is used to define the location of the switch region SR of the membrane circuit board. In some embodiments, the first membrane 110, the second membrane 120 and the spacer layer 130 may be made of a plastic material, such as polycarbonate (PC), polyethylene terephthalate (PET), polymethyl methacrylate (PMMA), polyurethane (PU) or polyimide (PI). The membrane made of the plastic material has characteristics of insulation, heat resistance, bendability and high resilience, which makes the membrane circuit board flexible and similar to a known flexible printed circuit (FPC) board.

As shown in FIGS. 1 and 2, the first carbon ink contact 140 is disposed on one of a portion of an upper surface of the first membrane 110 corresponding to the opening 130a and a portion of a lower surface of the second membrane 120 corresponding to the opening 130a. In some embodiments, as shown in FIGS. 1 and 2, the first carbon ink contact 140 is disposed on the portion of the upper surface of the first membrane 110 corresponding to the opening 130a. The first carbon ink contact 140 is metal-free.

As shown in FIG. 1, the corresponding contact 150 corresponds to (or can be called substantially aligned with) the first carbon ink contact 140, and is disposed on the other of the portion of the upper surface of the first membrane 110 corresponding to the opening 130a and the portion of the lower surface of the second membrane 120 corresponding to the opening 130a. In some embodiments, as shown in FIG. 1, the corresponding contact 150 is disposed on the portion of the lower surface of the second membrane 120 corresponding to the opening 130a. The corresponding contact 150 is a second carbon ink contact or a conductive contact (resistance of which is smaller than resistance of the first carbon ink contact 140).

In some embodiments, as shown in FIGS. 1 and 2, the membrane circuit board further includes a first conductive wire 160 (e.g., formed by silver paste), which is connected to the first carbon ink contact 140. In some embodiments, as shown in FIG. 1, the first carbon ink contact 140 includes a main pattern 140m and a connection pattern 140c connected to the main pattern 140m, and the connection pattern 140c is also connected to the first conductive wire 160. The connection pattern 140c is configured to indicate a position where the first conductive wire 160 is connected thereto. In some embodiments, one end of the first conductive wire 160 overlaps with the first carbon ink contact 140. In some embodiments, the first conductive wire 160 does not surround the first carbon ink contact 140. In other embodiments, one end of the first conductive wire may extend to the center of the switch region, and the first carbon ink contact is disposed over the end of the first conductive wire (not shown).

In some embodiments, referring to FIG. 1, the corresponding contact 150 is a second carbon ink contact. The second carbon ink contact is metal-free. The first carbon ink contact 140 and the second carbon ink contact may be made of the same or different carbon ink materials. The first carbon ink contact 140 and/or the second carbon ink contact may be formed through printing process(es). In some embodiments, the membrane circuit board further includes a second conductive wire 170 (e.g., formed by silver paste) connected to the second carbon ink contact. In some embodiments, the second conductive wire 170 does not surround the second carbon ink contact.

Please refer to FIG. 1, when the user does not press the key, the first carbon ink contact 140 and the corresponding contact 150 are not in contact with each other; when the user presses the key, the second membrane 120 is deformed (e.g., protruding downwardly) due to being pressed, and thus the corresponding contact 150 and the first carbon ink contact 140 are in contact with each other, and the first conductive wire 160 and the second conductive wire 170 conduct through the first carbon ink contact 140 (with high impedance) and the corresponding contact 150, resulting in the matrix signal with the specific high impedance value for the processor (e.g., a microcontroller unit (MCU)) to identify.

In practical applications, the shape, area and thickness of the first carbon ink contact 140 can be appropriately designed according to the applicable identification range of the processor for the impedance value of the matrix signal, so that after the first carbon ink contact 140 is in contact with and conducts with the corresponding contact 150, the matrix signal with the specific high impedance value can be generated for the processor to identify which specific key is pressed. Further, since the two contacts can be designed as the two carbon ink contacts (i.e. the first carbon ink contact 140 and the second carbon ink contact), or designed as the carbon ink contact (i.e. the first carbon ink contact 140) and the conductive contact, and different designs can be made for the shape, area and thickness of the carbon ink contact(s), so it is possible to quickly design contact combinations that can generate the matrix signals with the significantly different high impedance values, making it easier for the processor to identify which specific key is pressed.

In some embodiments, the membrane circuit board has a plurality of switch regions (referring to FIG. 2, which shows one switch region SR) and a peripheral region (or can be called a wiring region, referring to FIG. 2, not marked) surrounding the switch regions. However, there is no carbon ink material disposed on another portion of the upper surface of the first membrane 110 in the peripheral region (as shown in FIG. 2) and another portion of the lower surface of the second membrane in the peripheral region (not shown). Compared with disposing a high-impedance wire segment over a certain membrane in a peripheral region to connect a contact, in the present invention, the first carbon ink contact 140 that is directly disposed on the switch region of the first membrane 110 or the switch region of the second membrane 120 does not occupy the peripheral region, so that it does not affect layout of peripheral wires.

In addition, generally, in order to generate the matrix signal with the specific high impedance value (e.g., 2,000 ohms to 5,000 ohms) after the specific two contacts conduct, the design of the circuit layout of the peripheral region should be appropriately changed, which affects the circuit layout of the peripheral wires. However, in one embodiment of the present invention, the two carbon ink contacts (i.e., the first carbon ink contact 140 and the second carbon ink contact) that are respectively disposed on the switch region of the first membrane 110 and the switch region of the second membrane 120 can generate the matrix signal with the specific high impedance value (e.g., 2,000 ohms to 5,000 ohms) after the two carbon ink contacts conduct without changing the design of the circuit layout of the peripheral region, which does not affect the circuit layout of the peripheral wires.

In another aspect, in terms of the manufacturing process, printing the high-impedance wire segment with a smaller width for connecting the wire/contact is prone to errors; however, in the present invention, printing the carbon ink contact for connecting the wire is less prone to errors. In addition, the membrane circuit board may further have a tail region (not shown), which connects a portion of one side of the peripheral region, and the portion of the side of the peripheral region is located between the switch region and the tail region. In the tail region, a plurality of wires are disposed on the upper surface of the first membrane or the lower surface of the second membrane, and ends of the wires can be respectively provided with carbon ink patterns, so that the wires can be well electrically connected to a connector (not shown). The carbon ink patterns may be formed in the same printing process as the first carbon ink contact, and thus no additional process is required to form the carbon ink patterns.

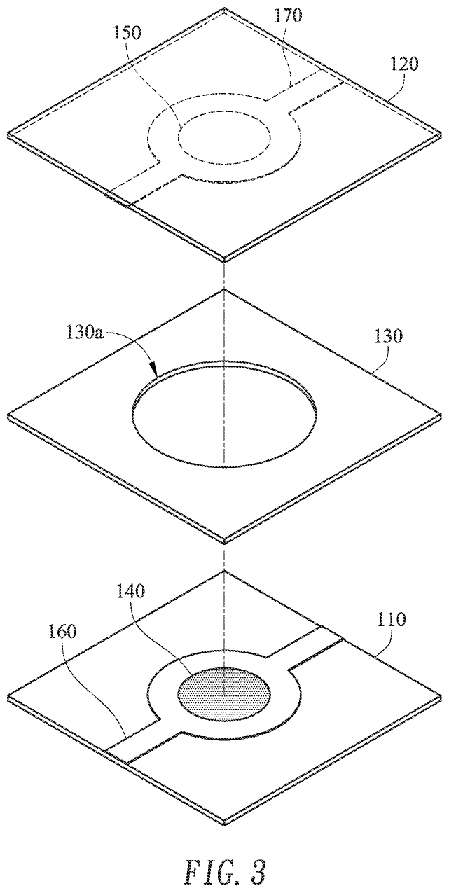

Other embodiments of the membrane circuit board of the present invention are provided below. FIG. 3 is an exploded perspective view of a membrane circuit board according to an embodiment of the present invention. In some embodiments, as shown in FIG. 3, the first conductive wire 160 surrounds at least a portion of the first carbon ink contact 140, or even surrounds the entire first carbon ink contact 140; the second conductive wire 170 surrounds at least a portion of the corresponding contact 150 (e.g., the second carbon ink contact), or even surrounds the entire corresponding contact 150.

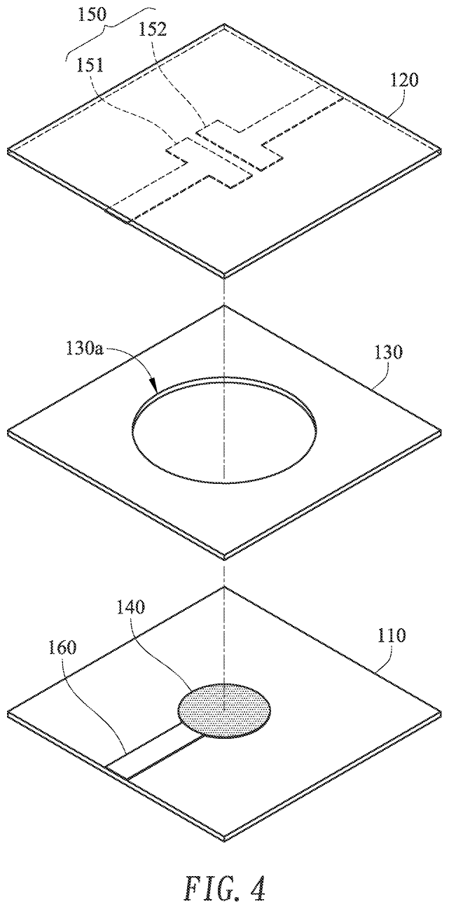

FIG. 4 is an exploded perspective view of a membrane circuit board according to an embodiment of the present invention. In some embodiments, as shown in FIG. 4, the corresponding contact 150 is a conductive contact (e.g., formed by silver paste), which includes a first portion 151 and a second portion 152, and the first portion 151 and the second portion 152 are separated by a gap. In some embodiments, the first portion 151 and the second portion 152 extend to the peripheral region.

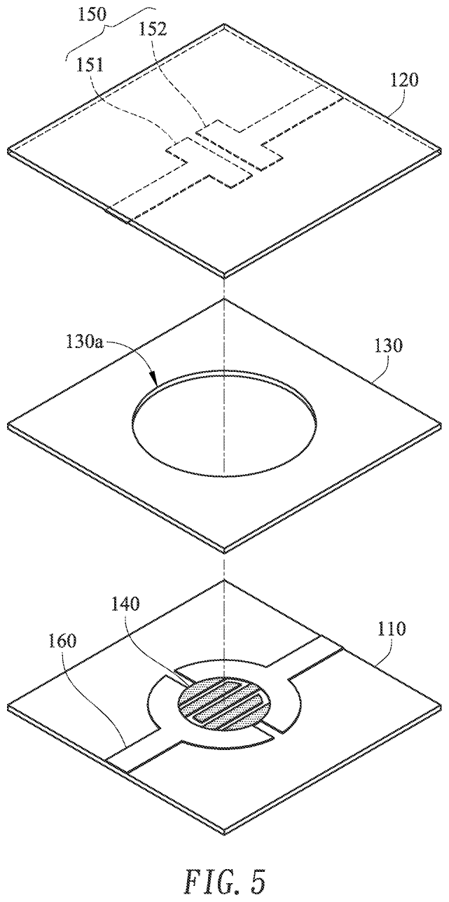

FIG. 5 is an exploded perspective view of a membrane circuit board according to an embodiment of the present invention. In some embodiments, the first carbon ink contact 140 includes a plurality of strip-shaped carbon ink contacts. In some embodiments, the first conductive wire 160 surrounds at least a portion of the first carbon ink contact 140.

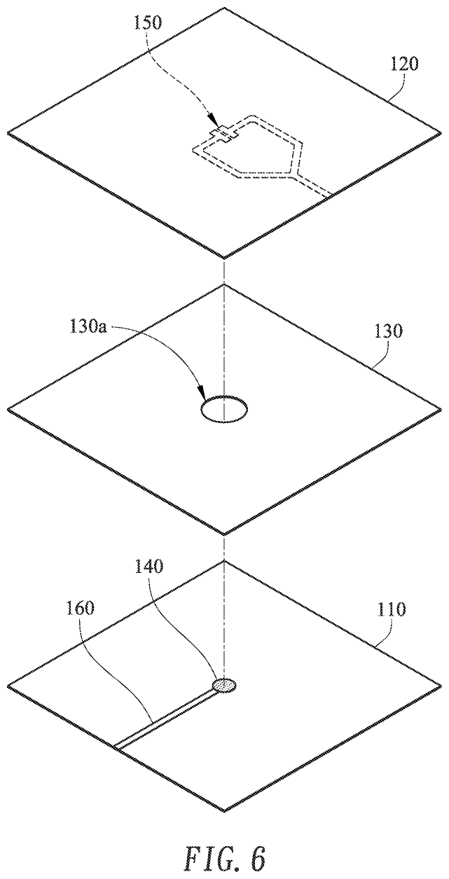

FIG. 6 is an exploded perspective view of a membrane circuit board according to an embodiment of the present invention. In some embodiments, as shown in FIG. 6, the corresponding contact 150 is a conductive contact (e.g., formed by silver paste), and two ends of the conductive contact are separated by a gap. In some embodiments, the corresponding contact 150 extends to the peripheral region.

However, the above are only the preferred embodiments of the present disclosure, and should not be used to limit the scope of implementation of the present disclosure, that is, simple equivalent changes and modifications made in accordance with claims and description of the present disclosure are still within the scope of the present disclosure. In addition, any embodiment of the present disclosure or claim does not need to achieve all the objectives or advantages disclosed in the present disclosure. In addition, the abstract and the title are not intended to limit the scope of claims of the present disclosure.

What is claimed is:

1. A membrane circuit board, having at least one switch region, the membrane circuit board comprising:
a first membrane;
a second membrane, located over the first membrane;
a spacer layer, located between the first membrane and the second membrane, and having an opening in the at least one switch region;
a first carbon ink contact, disposed on one of a portion of an upper surface of the first membrane corresponding to the opening and a portion of a lower surface of the second membrane corresponding to the opening; and
a corresponding contact, corresponding to the first carbon ink contact, and disposed on the other of the portion of the upper surface of the first membrane corresponding to the opening and the portion of the lower surface of the second membrane corresponding to the opening, wherein the corresponding contact is a second carbon ink contact or a conductive contact, and resistance of the conductive contact is smaller than resistance of the first carbon ink contact.

2. The membrane circuit board of claim 1, wherein the membrane circuit board has a plurality of switch regions and a peripheral region surrounding the switch regions, and there is no carbon ink material disposed on another portion of the upper surface of the first membrane in the peripheral region and another portion of the lower surface of the second membrane in the peripheral region.

3. The membrane circuit board of claim 1, further comprising:
a first conductive wire, connected to the first carbon ink contact.

4. The membrane circuit board of claim 3, wherein the first carbon ink contact comprises a main pattern and a connection pattern connected to the main pattern, and the connection pattern is also connected to the first conductive wire.

5. The membrane circuit board of claim 3, wherein one end of the first conductive wire overlaps with the first carbon ink contact.

6. The membrane circuit board of claim 3, wherein the first conductive wire does not surround the first carbon ink contact.

7. The membrane circuit board of claim 3, wherein the first conductive wire surrounds at least a portion of the first carbon ink contact.

8. The membrane circuit board of claim 3, wherein the corresponding contact is the second carbon ink contact, and the membrane circuit board further comprises:
a second conductive wire, connected to the second carbon ink contact.

9. The membrane circuit board of claim 1, wherein the corresponding contact is the conductive contact, which includes a first portion and a second portion, and the first portion and the second portion are separated by a gap.

10. The membrane circuit board of claim 1, wherein the corresponding contact is the conductive contact, and two ends of the conductive contact are separated by a gap.
